(19) United States
(12) Patent Application Publication
(10) Pub. No.: US 2024/0072689 A1
(43) Pub. Date: Feb. 29, 2024

(54) POLYANGULAR SPECULAR MINI-STRUCTURE FOR FOCUSED, SOLAR-ENERGY SUPPLIED BATTERY

(71) Applicant: SOLMET LLC, New York, NY (US)

(72) Inventor: SAN CHENG, Mt. Laurel, NJ (US)

(73) Assignee: SOLMET LLC, New York, NY (US)

(21) Appl. No.: 18/237,267

(22) Filed: Aug. 23, 2023

Related U.S. Application Data
(60) Provisional application No. 63/401,419, filed on Aug. 26, 2022.

(51) Int. Cl. H02N 3/00

(52) U.S. Cl. CPC H02N 3/00

(57) ABSTRACT

A polyangular, specular, mini-structure comprises a faceted, hollow sphere, with an aperture and focusing lens within such aperture permitting sunlight to enter the interior of such faceted sphere. The facets are hexagonal and their inner surfaces are specular such that light entering the sphere is reflected multiple times. The faceted surfaces include silicon carbide or tungsten trioxide responsive to a stimulation current. The faceted surfaces may also comprise nickel manganese cobalt oxides and the interaction of such nickel manganese cobalt oxides with the reflected sunlight produces electric potential suitable for powering devices, installations, and electric vehicles, in the manner of a battery.

### FIELD

This disclosure relates to solar power generation and more particularly, to a polyangular specular mini-structure to supply electricity.

### BACKGROUND

The concept of capturing solar energy to produce electricity is known, and includes conventional photovoltaic systems. Current solar energy systems likewise may involve a focusing system known as concentrator photovoltaics (“CPV”), which uses lenses or other specular structures to focus sunlight onto small, highly efficient, multi junction solar cells.

Such CPV systems likewise use computer programming to increase their efficiency. Such computer programming is generally linked to physical devices for tracking of the sun, referred to as solar trackers.

There has also been work on polyangular specular reflector designs for ultra-high spectrum splitting and resulting increases in solar module efficiencies (see, Polyhedral Specular Reflector Design for Ultra-High Spectrum Splitting Solar Module Efficiencies (>50%), Eisler et al, SPIE, Calif Institute of Technology, 2013.

These and still other solar power systems of the current art suffer from various drawbacks and disadvantages, including the need to manage thermal energy, and the drop of efficiency or operability outside of sunny days or outside of optimal conditions.

For example, the most suitable temperature for traditional solar panels and corresponding solar cells for energy conversion ranges between about twenty three to about twenty eight degrees Celsius. Outside of such suitable range, temperature conversion rates and other operating parameters decline steeply. In addition, solar cells and traditional solar panels are relatively expensive, made out of silicon carbide. Furthermore, optimal energy conversion from solar radiation is obtained primarily under direct sunlight and even under such circumstances, costs of conversion of direct sunlight to electrical energy is relatively high, making solar energy less sought after than other energy sources.

Lithium nickel manganese cobalt oxides are mixed metal oxides (often abbreviated LiNMC, LNMC, NMC, or NCM, hereinafter referred to as “NMC”). NMC batteries are found in many electric cars.

### SUMMARY

In one implementation, a power mini-structure is in the form of a faceted sphere in which a number of hexagons form the facets. The outer sphere surface comprises NMC and the inner surfaces of the facets comprise specular surfaces. An aperture is formed in the faceted sphere through which focused sunlight enters the hollow interior of the faceted sphere and is reflected multiple times by the interiorly-oriented specular facets.

In other implementations, a polyangular specular mini-structure has a plurality of facets arranged to form a hollow, faceted sphere, the facets being composed of quartz, silica sand, tungsten trioxide, silicon carbide, single crystal silicon, or silicon dioxide, either alone or in various composites, compositions, and metallurgical fusions of the forgoing.

In a related implementation, the facets are composed of quartz, silica sand, and tungsten trioxide which have been combined together at suitable temperatures so as to form a glass glue liquor. The foregoing structure has silicon carbide, single crystal silicon, and silicon dioxide added to the glass glue liquor while such liquor is in its liquid state. The facets thereafter comprise both the glass glue liquor and the foregoing additives after cooling of the admixture.

In one suitable implementation, the facets comprise a sufficient amount of tungsten trioxide to cause ion emission in response to stimulation of the tungsten trioxide with a stimulation current of electricity. According to the disclosure, this stimulation current has a value of 4 amp-hours (Ah), and the amount of tungsten trioxide is selected so as to be responsive to a stimulation current of such magnitude.

According to the disclosure, the facets are adapted so that, when subjected to the stimulation current, the ion emissions are reflected internally within the polyangular specular mini-structure, generating electricity until an electric generation threshold has been reached. Thereafter, upon reaching such electric generation threshold, the facets transmit light therethrough until the ion emission falls below the electric generation threshold. As such, the facets of the polyangular specular mini-structure generate a supply of electricity at greater amp-hours than the stimulation current.

The foregoing features of the mini-structure implementation may be paired with suitable computer programming, including artificial intelligence components thereof, for controlling the stimulation current in terms of timing, amount, and duration, in response to the generation of the supply electricity.

Suitable implementations for the mini-structure have been formed into diameters of 6 mm, 1.2 cm, 3 cm, and 6 cm, with corresponding electricity supplied, respectively, at 10 kW, 25 kW, 100 kW, and 300 kW.

The layers of a polyangular specular mini-structure according to suitable implementations may be concentric to each other starting from an innermost layer consisting essentially of a mixture of silicon carbide and single crystal silicon, followed by silicon dioxide, a mixture of quartz and quartz sand to form a glass layer, silver nitrate, and silver sulfide.

Among the possible methods of manufacturing a polyangular specular mini-structure, one suitable technique involves creating a glass glue liquor and adding silicon carbide, single-crystal sand, and silicon dioxide to form a resultant liquor. The resultant liquor may then be supplied to a 3-D printing apparatus as a raw material, from which 3-D printing operations form a polyangular specular mini-structure. The polyangular specular mini-structure may be associated with a mirror group so as to focus light beams into the aperture of the sphere or mini-structure and supply the requisite stimulation current thereby.

In still further implementations, polyangular specular mini-structures composed of any of the materials set forth in this disclosure, may be arranged and interconnected to form an array of such mini-structures, affixed to a panel, and thereby either form a battery or supplement a battery for an electric vehicle.

In still further implementations, arrays and associated panels of the polyangular specular mini-structures disclosed herein may be configured to power portable electronic devices, such as smart glasses, smartphones, drones, and residential homes.

The foregoing summary and this disclosure will be better understood with reference to the drawings, in which:

### BRIEF DESCRIPTION OF DRAWINGS

FIG. 1A and FIG. 1B are perspective and side sectional views, respectively, of a power mini-structure in the form of a polyangular, specular faceted sphere;

FIG. 2A and FIG. 2B are exploded and schematic views of a focusing lens group suitable for an aperture formed in the faceted sphere shown in FIG. 1;

FIG. 3 is an isometric view of an array of polyangular specular mini-structures for use as a battery or in conjunction with a battery of an electric vehicle;

FIG. 4 are perspective schematic views of still further applications of polyangular specular mini-structures according to the present disclosure;

FIG. 5 is a partly schematic view of an embodiment of the polyangular specular mini-structure according to the present disclosure, in a test environment;

FIG. 6 is a cross-sectional view of an embodiment of the polyangular specular mini-structure, according to the disclosure herein; and

FIG. 7 is an enlarged sectional view of the cross-section of FIG. 6.

### DETAILED DESCRIPTION

In one implementation, with the foregoing background in mind, an improved solar energy system, which is the subject of this disclosure, comprises multiple, polyangular specular mini-structures to produce focused solar energy for use in batteries for devices, such as electric vehicle batteries.

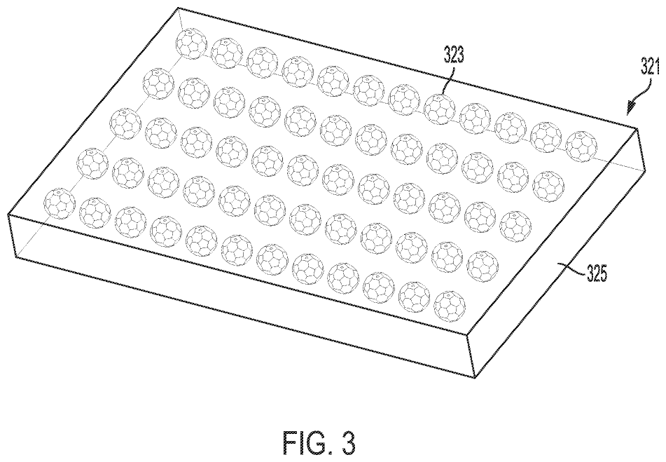

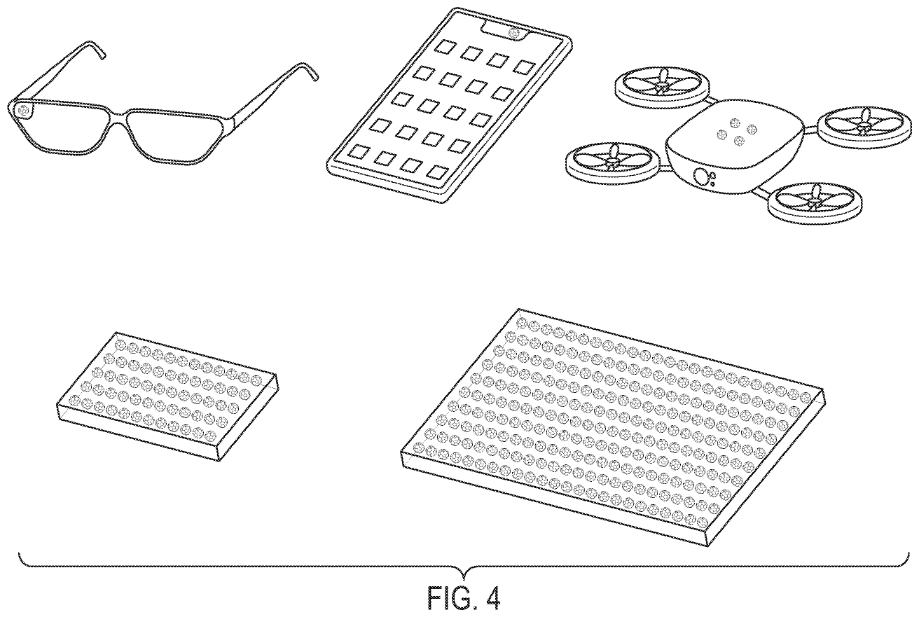

As such, a solar-energy-powered battery 321 as shown in FIG. 3 comprises an array of polyangular specular mini-structures 323, also known as crystal-like pearls, light-fusion or light-focusing crystals, photon energy spheres, or PES (singular or plural). The multiple polyangular specular mini-structures 323 arranged on a panel 325 focus solar energy by virtue of their configuration shown in FIG. 3. In one preferred implementation, the panel 325 is a square of about ten inches (10″), and has one hundred (100) light fusion crystals configured to reflect or refract light in different ways, whether from direct sunlight, overcast or diffuse sunlight, or light sources after sunset.

The plurality of light fusion crystals or light focusing crystals absorb solar energy and convert such energy to heat, but more importantly, to an electric potential arising from ionization of NMC or other material capable of ionization. This electric potential is linked to the power system of the device or system requiring power, such as for electric vehicle, either as a stand-alone NMC battery or supplement thereto.

The panel 325 shown and described herein can also be used wherever current solar energy uses, and like installations, are found, such as for home use, within companies, factories, government facilities, military. The panel can likewise be used as a battery for buses to travel unlimitedly.

In one possible implementation, shown schematically in FIG. 3, 100 light fusion crystals are in the 10-inch panel, 15 are direct ray of intense light emitted from the sun, 35 are light import from rainy days or cloud transmission, 50 low light imports from the night light source. The lens orientation of the fusion crystals may be controlled by suitable software. Elements are used within the panel to absorb light energy, heat energy and electrical energy. The three energy sources may be introduced into hydrogen energy batteries to store electricity.

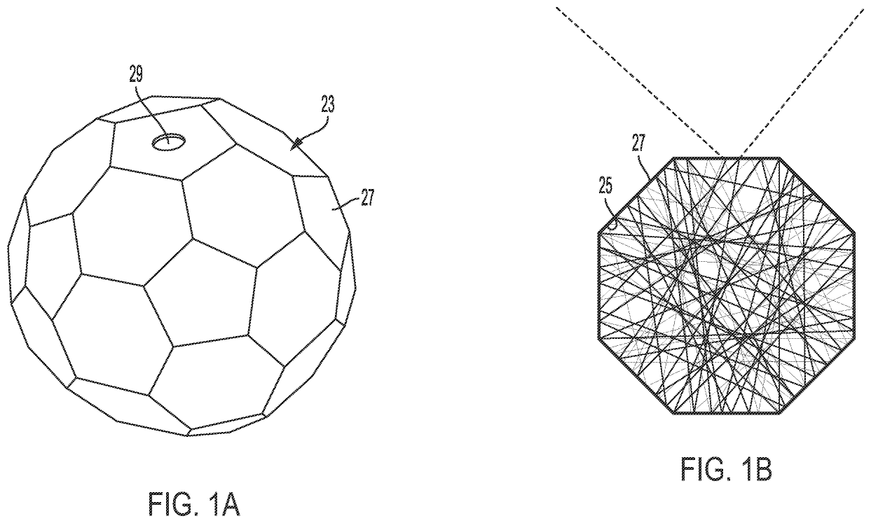

Referring now to FIGS. 1A and 1B, according to one suitable implementation, polyangular specular mini-structures 23 are hollow, having inner and outer surfaces 25, 27, and an aperture 29 through which solar light enters the inside. In one preferred arrangement, the mini-structure is in the form of a faceted sphere and has a diameter of 3.6 cm and 360 hexagons forming the facets. The preferred diameters of individual spheres may range from 6 mm to 80 mm. In one implementation, the outer surface of the faceted spheres comprises nickel or NMC, whereas the inner surfaces are reflective. The walls of the structures/spheres may comprise glass or other carrier material, either of which is treated or coated with NMC. The specular structures are preferably spheres faceted with hexagonal structures, the interior being hollow and the interior surfaces of the hexagons being mirrored, specular, or otherwise reflective.

Opening 29 permits solar light to enter the interior of specular mini-structure 23, where it is reflected countless times. The reflective faceted inner surface 25 generates heat or ionizing radiation with regard to its constituent material, such as the NMC material. The reflected solar radiation produces a corresponding electric potential to form a battery to power the associated device or written installation. Based on early tested digital results with a heat measuring instrument, energy output exceeded the instruments maximum limit of 500 KW. Accordingly, in further testing, 100 MW is a very conservative estimate and is not the final result as well.

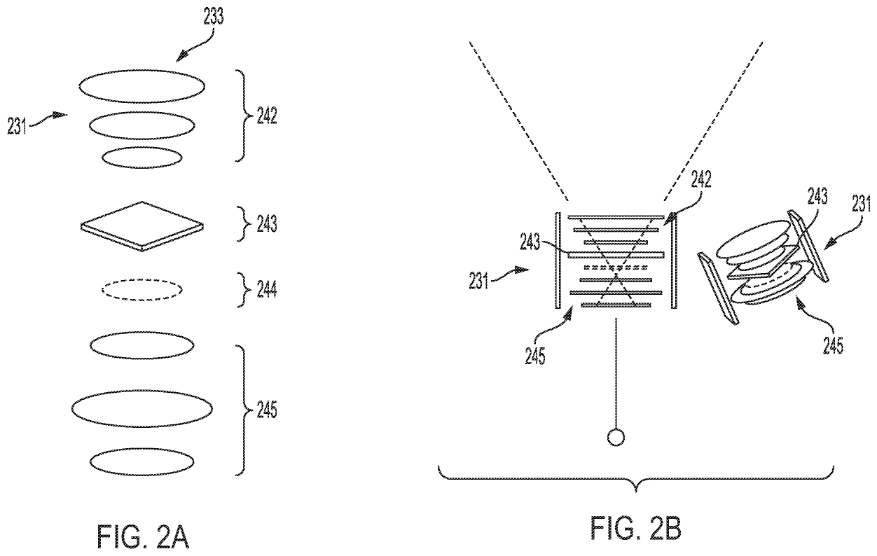

The solar light, in turn, is focused by a series of lenses 231 shown in FIGS. 2A and 2B, and constituting a focusing mirror group design 233. Such mirror group design 233 preferably comprises an object lens group 242, a prism group 243, a focusing lens/mirror 244, and an eye piece group 245.

The particular optics of the focusing mirror group design 233 have been suitably made with the following characteristics: All are the same size outer circumference with different thicknesses, arranged as shown in FIGS. 2A and 2B, according to the size of each of the specular mini-structures 23, 323 from the panel 325 in FIG. 3, as follows:
1) 2.5 mm*16 mm,
2) 1.6 mm*16 mm,
3) 4.5 mm*16 mm,
4) 3.0 mm*16 mm

The dimensions adjust according to the proportions of mini-structure 23.

The polyangular specular mini-structure 23 disclosed herein has been found suitable with the following characteristics relating to its interior surface structure, faceted sides, and overall dimensions as follows: each pearl: 3.6 cm*3.6 cm, with 360 hexagons.

The panel 325 for use in connection with an electric vehicle battery shown in FIG. 3 generates an electric potential by interfacing the array of specular structures to the NMC battery or to serve as a replacement for the traditional battery.

In another implementation, a polyangular specular mini-structure has facets composed of one or more of the following materials: quartz, silica sand, tungsten trioxide, silicon carbide, single-crystal silicon, and silicon dioxide. In certain implementations, the facets have a sufficient amount of the tungsten trioxide such that, when they are subject to a stimulation current, ion emission occurs. The composition and amount of tungsten trioxide are selected so that, in response to the stimulation current, the ion emissions are reflected within the mini-structure sufficiently to first charge the mini-structure up to an electric generation threshold, and, thereafter, upon reaching such electric generation threshold, to transmit light for reflection within or through the mini-structure until the ion emission falls below the electric generation threshold. The transmission of light, or reflection of light beams, in turn, reacts with the facets and materials from which the facets are composed, so as to generate a supply of electricity at greater amp-hours than the stimulation current.

In still another potential implementation, computer programming, whether adaptive programming or artificial intelligence-related generative instructions, are operatively associated with the foregoing operations of the polyangular specular mini-structure, so as to control the stimulation current in terms of timing, amount, and duration, in response to the generation of the supply electricity.

The polyangular specular structure 23 may find application as a power source, such as a battery, in any number of devices, including consumer electronics devices shown in FIG. 4.

The principle of operation of such power source is apparent to one of skill in the art from the foregoing description. The polyangular specular structure 23 (again, also referred to as a photon energy sphere or PES), compresses strong beams of light of over 0.5 mm through mirror group 233, which are reflected hundreds of millions of times per second in the 360-facet implementation of mini-structure 23. Together with silicon carbide, monocrystalline silicon, and silicon dioxide, the strong beams and silicon structure will form an electron vortex. The strong beams and electron vortices generate electricity through a suitable optical-to-electrical module, which is charged into various batteries through an inverter unit that converts direct current and alternating current.

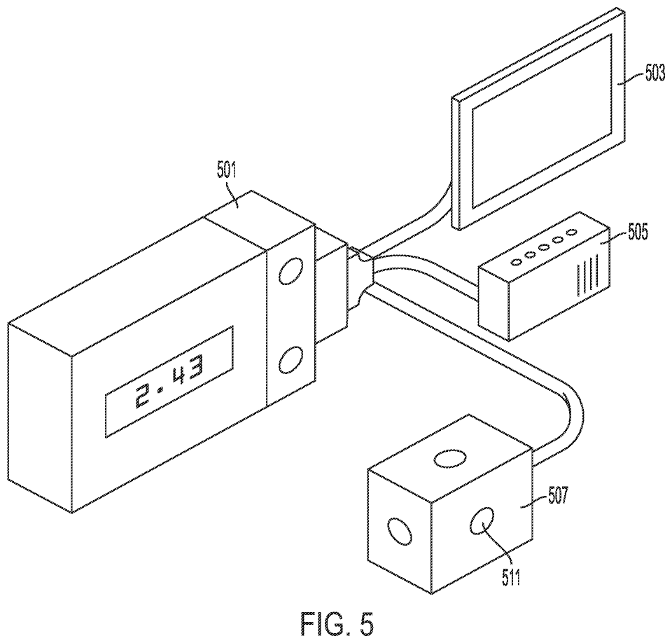

The 360 hexagonal-cut PES glass spheres (mini-structures 23) have been formed in different sizes and have been passed through a suitable electric wattage power test apparatus, such as that in FIG. 5, with the current test results as follows:

Each 6 mm sphere can generate 10 kW of electricity in one second, which can be used for a variety of electronic products such as smartphones, tablets, laptops, smart glasses and so on.

Each 1.2 cm sphere can generate 25 kW of electricity in one second, which can be used for electric locomotives, electric scooters, lightweight drones, and a variety of smart home appliances.

Each 3 cm sphere can generate 100 kW of electricity in one second, which can be used for electric vehicles, eVTOL (Electric Vertical Take-off and Landing), air cabs, intelligent street lights, UAV, various military laser weapons, satellites, airbase stations, and various means of transportation.

Each 6 cm sphere can generate 300 kW of electricity in one second, which can be used for apartments, office buildings, manufacturing plants, shopping centers, desalination plants, various ships, all government facilities, all military bases, and so on.

According to the current experimental results, glass spheres with 360 hexagonal cuts are the most energetic, and spheres with 60 or 120 hexagonal cuts also work well and produce relatively less energy. Combinations that also work well are glass spheres made of 60 or 120 or 360 pentagonal cuts, glass spheres made of 60 or 120 or 360 mixed pentagonal and hexagonal cuts, and glass spheres made of 60 or 120 or 360 triangular cuts, which also produce relatively less energy. The entirety of the sphere without cuts or with still fewer cuts may likewise generate electricity at a very low efficiency.

The foregoing wattage generations are associated with tests using an electric wattage power test apparatus, such as that shown schematically in FIG. 5. An electric wattage power test meter, such as that made by MOLECTRON, in the form of a laser power meter 501, is interconnected with a suitably programmed computer 503, such as a tablet, running adaptive programming for electronic and wattage control, and a ternary polymer lithium battery 505. One significant aspect of the testing apparatus and corresponding results relate to an optoelectronic module 507 in which a 6 mm-diameter PES 511 is substantially contained. PES 511 may comprise facets and be formed of any of the combinations of materials disclosed herein when manufactured by the 3D printer mode set out herein. The optoelectronic module 507 allows PES 511 to receive incoming light, such as solar light, at an amount, such as in amp-hours, to provide a stimulation current to PES 511.

In response to said stimulation current, PES 511 generates supply electricity which is shown in the laser power meter as 2.43 kw for a duration of 0.5 seconds. The supply electricity, in turn may charge ternary polymer lithium battery 505.

With regard to the arrays or panels 325 of multiple PES structures, such as those shown in FIGS. 3 and 4, a 9×9 cm panel has AI programming, and is made up of nine 3 cm spheres. Such dimensions may be will be used in electric vehicles (with a panel size smaller than two iPhones), of which three spheres are mainly responsible for capturing the sun's direct light sources, which can be instantly charged into all batteries, another three spheres are responsible for capturing weak light sources such as sunset or rainy light, and the remaining three spheres are responsible for capturing the continuous source of light. A continuous source of light may be a relatively small light source, as compared to solar light, such as street lamps at night, various signboards or store light source. This light source, while weak light or shimmering light, may maintain or stimulate the PES sphere, and can thus become a permanent energy source without the need to dedicate further light. If the continuous source of light is captured successfully, it can be used for time ranging from a few months to a year. Similarly, different arrangements and combinations of PES structures may be devised according to different environments to meet power needs.

Each PES has an independent light measurement sensor and AI chip, allowing it to constantly adjust the direction of capturing the light source during operation. Even in environments with no light source at all, small LED light-emitting devices may serve as sources for the PES, so that the PES is capable of charging.

At present, there are three workable modes of manufacture of the PES structures or glass spheres (mini-structures 23).

In one possible implementation, the following steps are performed using suitable materials processing techniques and related equipment for such processing: Melt quartz, silica sand and tungsten trioxide into glass glue liquor, and add silicon carbide, single crystal sand and silicon dioxide into the liquid. Use a precision industrial 3D printer to transform the glass glue liquor into transparent sphere layer by layer. In one suitable implementation, recycled glass was found suitable as a raw material for use with the disclosed 3D printing process.

Finally, glue or otherwise affix the miniature mirror group above the sphere.

It is expected, from certain tests and related calculations, that by stimulating tungsten trioxide with 4 ah (amp-hours) of electricity, the entire transparent glass sphere will turn into an ionic mirror. Light exits the PES and passes through the mirror group to produce a polar beam, which is reflected billions of times in the mirror sphere. So the sphere is generally completely transparent. When electricity is required, the PES comes into a completely mirror-like state in response to re-stimulation of the tungsten trioxide at a suitable stimulation current, such as 4 amp-hours. Again, when the PES is fully charged and is about to discharge, it will return to the glass state, and all beams of light will leak through transparent glass. A specially designed AI chipset controls the electric current and electronic stimulation associated with this iterative process.

Another suitable method of manufacture involves metallurgical mold processes such as those making use of a unibody mold opening. Firstly, stainless steel is used to open an inner mold and an outer mold. The inner mold is polyhedral stainless steel ranging from 30 to 720 facets, and the outer mold is spherical stainless steel. For the proposing mold surfaces, whether faceted or not, it is preferable for the surfaces to have similar areas to promote refraction. The thickness of the inner and outer molds is 2 mm, and a hole with a diameter of 5 mm is left above. Soda ash, limestone and quartz are melted at respective melting points to form a glass glue liquor at a high temperature of 1,600° C., and the liquor is poured through the 5 mm hole. Then, rotary heat is applied to 600° C. for molding. After water cooling and gas cooling, the mold is opened to remove the glass sphere from the mold. Silicon carbide, monocrystalline silicon, silicon dioxide are sprayed into the 5 mm hole to form a coating within the molded, faceted sphere. The miniature mirror group is placed operatively adjacent to the 5 mm hole. A further 1.2 mm aperture is formed in the PES sphere, such as at a location opposite the 5 mm hole.

In operation, the aperture is then controlled with a motor aperture for cameras, and the surrounding area is covered with graphene. An AI chip is used to control the current and drive electricity generation operations of the sphere. It is possible to control the direction of the sphere after it is fully charged, and turn the aperture to a position where there is no grapheme, thereby draining all beams of light out, and thereafter returning the sphere to its limited position before such turning.

In still another possible implementation, the molding processes involve a hemi mold-opening. The design of the sphere is divided into two hemispherical molds, with the top mold being a polyhedral stainless steel mold and the bottom being a spherical stainless steel mold. The associated steps comprise the following: Quartz sand and quartz are melted into glass glue liquor at a high temperature of 1,600 degrees, which is poured into the bottom mold pressed by the top mold. Thereafter, it is possible to rapidly mold the molded hemispherical modules with cooling gas. Impurities are removed with UV and then the molded output is polished with ammonia. The resultant molded, faceted components are treated to form a coating with silicon carbide, monocrystalline silicon and silicon dioxide. A laser is used to stitch the two hemispheres together with glass liquor or grapheme to form a complete sphere. It is then possible to coat the outside of the sphere with silver nitrate and silver sulfide to form a mirrored sphere. A 1.2 mm transparent glass port is left to form an aperture for use in electricity generation operations.

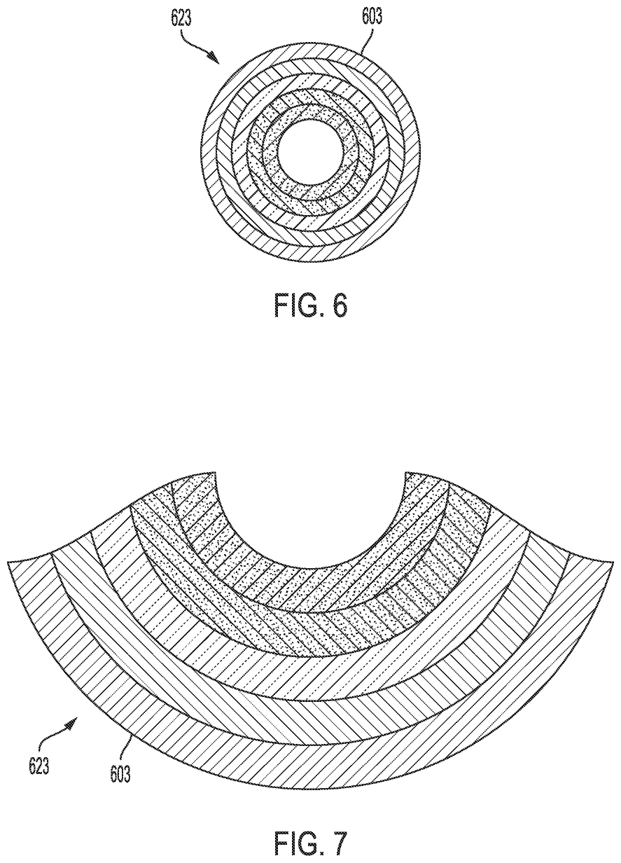

Referring to FIGS. 6 and 7, in one suitable implementation of a PES and the foregoing manufacturing process set forth immediately above, it is expected that concentric layers may be formed in PES 623, and provided with corresponding facets 603, with the innermost layer comprising a mixture of silicon carbide and single crystal silicon having a thickness of 0.18 mm, and with successive overlying layers comprising silicon dioxide having a thickness of 0.22 mm, a mixture of quartz and quartz sand to form a glass layer having a thickness of 2 mm, silver nitrate having a thickness of 0.5 mm, and silver sulfide having a thickness of 0.8 mm. Thereafter a miniature mirror group such as that shown in FIGS. 2A and 2B, may be placed in operative proximity to the above-described faceted sphere. An AI chip may completely guide the current control and light emanations from PES 623.

The advantages of the foregoing power mini-structure and related systems and applications are apparent from the foregoing description. In general terms, the light entering the specular, faceted spheres creates a thermal energy which can be maintained and thus become a sustainable energy source, substantially unaffected by temperature and climate. The sun's daylight hours likewise do not degrade the performance of the specular, faceted spheres having received light therein and the economics of the electrical energy created thereby have minimal conversion losses, unlike traditional solar cells, and therefore maintain conversion ratios at or closer to one hundred percent in the disclosed embodiments. Furthermore, unlike the silicon carbide of solar cells, the faceted, NMC mini-structures are relatively small and inexpensive.

What is claimed is:

1. A polyangular specular mini-structure, comprising:
a hollow, faceted sphere, wherein the facets comprise hexagons;
wherein the faceted sphere has an aperture formed therein;
a focusing lens group operatively associated with the aperture and configured to focus sunlight impinging on the focusing lens group; and
wherein the inner surfaces of the facets comprise specular surfaces, the specular surfaces reflecting the sunlight entering the faceted sphere a plurality of times;
whereby at least one of heat and electrical energy are produced.

2. The polyangular specular mini-structure of claim 1, wherein the sphere is formed of 360 hexagonal facets and has a diameter ranging from 6 mm to 80 mm.

3. The polyangular specular mini-structure of claim 1, wherein a plurality of the power structures are arranged and interconnected in a suitable grid to form a battery for an electric vehicle.

4. The polyangular specular mini-structure of claim 3, wherein the array of mini structures are affixed to a panel and the output of the mini-structures are fed into an interface for use within an electric vehicle battery.

5. The polyangular specular mini-structure of claim 1, wherein the power outputted therefrom is inputted into a portable electronic device.

6. The polyangular specular mini-structure of claim 5, wherein the portable electronic device is selected from the group consisting of smart glasses, smartphones, drones, and residential homes.

7. The polyangular specular mini-structure of claim 1, wherein the outer surface of such facets comprising oxides of at least one of lithium, nickel, manganese, and cobalt.

8. The polyangular specular mini-structure of claim 1, wherein the facets are composed of at least one material selected from the group consisting of quartz, silica sand, tungsten trioxide, silicon carbide, single crystal silicon, and silicon dioxide.

9. The polyangular specular mini-structure of claim 8, wherein the facets are composed of the quartz, silica sand, and tungsten trioxide combined together at suitable temperature into a glass glue liquor, to which the silicon carbide, the single crystal sand, and the silicon dioxide are added to the glass glue liquor as additives in a liquid state, the facets comprising the glue glass liquor and the additives upon cooling thereof.

10. The polyangular specular mini-structure of claim 9, wherein the facets comprise a sufficient amount of the tungsten trioxide to cause ion emission in response to stimulation of the tungsten trioxide with a stimulation current of electricity.

11. The polyangular specular mini-structure of claim 10, wherein the stimulation current has a value of 4 amp-hours (Ah), and wherein the amount of tungsten trioxide is selected to be responsive to the stimulation current.

12. The polyangular specular mini-structure of claim 10, wherein the facets are adapted, in response to the stimulation current, to reflect the ion emission until an electric generation threshold is reached, and wherein, upon reaching the electric generation threshold, the facets transmit light therethrough until the ion emission falls below the electric generation threshold; and wherein the facets generate supply electricity at greater amp-hours than the stimulation current.

13. The polyangular specular mini-structure of claim 12, further comprising computer programming for controlling the stimulation current in terms of timing, amount, and duration, in response to the generation of the supply electricity.

14. The polyangular specular mini-structure of claim 12, wherein the spheres comprise diameters selected from the group consisting of: 6 mm, 1.2 cm, 3 cm, and 6 cm; and wherein the supply electricity for the 6 mm, 1.2 cm, 3 cm, and 6 cm spheres comprises, respectively, 10 kW, 25 kW, 100 kW, and 300 kW.

15. The polyangular specular mini-structure of claim 8, wherein the sphere comprises a plurality of concentric layers, the facets formed from the layers, and wherein the material of respective ones of the layers consist essentially of (1) a mixture of silicon carbide and single crystal silicon, (2) silicon dioxide, (3) a mixture of quartz and quartz sand to form a glass layer, (4) silver nitrate, and (5) silver sulfide.

16. A method of manufacturing a polyangular specular mini-structure, the method comprising the steps of:
melting quartz, silica sand, and tungsten trioxide into glass glue liquor;
adding silicon carbide, single crystal sand, and silicon dioxide into the glass glue liquor to form a resultant liquor;
supplying the resultant liquor to 3-D printing apparatus as raw material therefor;
performing 3-D printer operations to form a sphere comprising the components of the resultant liquor;
forming an aperture in the sphere; and
affixing a plurality of mirrors selected to focus light beams on the aperture of the sphere.

17. A method of manufacturing a polyangular specular mini-structure, the method comprising the steps of:
providing a unibody mold suitable for metallurgical processing, the unibody mold having a mold opening;
forming inner and outer molds, the inner mold comprised of polyhedral stainless steel ranging from 30 to 720 facets, and the outer mold comprised of spherical stainless steel;
selecting the thickness of the inner and outer molds to be 2 mm, and the opening to have a diameter of 5 mm;
melting soda ash, limestone, and quartz into a glass glue liquor at a temperature of 1,600° C.;
pouring the liquor through the hole into the unibody mold;
subjecting the unibody mold to rotary heat at 600° C.;
cooling the unibody mold and extracting the resultant glass sphere therefrom;
spraying silicon carbide, monocrystalline silicon, and silicon dioxide into the hole to form a coating within the glass sphere;
providing a plurality of mirrors operatively proximate to the opening; and
forming a hole opposite the opening, said hole smaller than the opening.

18. A method of manufacturing a polyangular specular mini-structure, the method comprising the steps of:
providing two, hemispherical molds;
heating silicon carbide, single crystal silicon, silicon dioxide, quartz, quartz sand, silver nitrate, and silver sulfide to their respective melting points for subsequent addition to the molds;
pouring respective ones of the foregoing compositions into the molds while in liquid state;
forming concentric layers including innermost and outermost layers thereof;
molding corresponding facets on at least the innermost and outermost layers;
forming the innermost layer as a mixture of silicon carbide and single crystal silicon having a thickness of 0.18 mm;
forming successive layers overlying the innermost layer, the successive layers comprising a silicon dioxide layer having a thickness of 0.22 mm, a mixture of quartz and quartz sand to form a glass layer having a thickness of 2 mm, a silver nitrate layer having a thickness of 0.5 mm, and a silver sulfide layer having a thickness of 0.8 mm; and
wherein the outermost layer comprises the silver sulfide layer.

19. A method of generating electricity from light, the method comprising:
providing facets of a polyangular specular mini-structure with a glass glue liquor, including tungsten trioxide therein, and additives of silicon carbide, single crystal sand, and silicon dioxide;
stimulating the tungsten trioxide of the sphere with four amp-hours (Ah) to cause ion emission in response thereto;
generating electric potential in response to impingement of the ion emission on the materials of which the facets are comprised; and
controlling by suitable software programming the stimulation current in terms of timing, amount, and duration, in response to the electric potential generated, whereby electricity is produced in response to stimulation of the sphere.
